(19) United States
(12) Patent Application Publication
(10) Pub. No.: US 2025/0046646 A1
(43) Pub. Date: Feb. 6, 2025

(54) SUBSTRATE PROCESSING APPARATUS AND SUBSTRATE MAP GENERATING METHOD

(71) Applicant: Tokyo Electron Limited, Tokyo (JP)

(72) Inventors: Junnosuke TAGUCHI, Iwate (JP); Ryotaro TAKAHASHI, Iwate (JP)

(21) Appl. No.: 18/782,696

(22) Filed: Jul. 24, 2024

(30) Foreign Application Priority Data
Aug. 2, 2023 (JP) 2023-126379

(51) Int. Cl. H01L 21/687; H01L 21/67

(52) U.S. Cl. CPC H01L 21/68764; H01L 21/67259; H01L 21/67288; H01L 21/68771

(57) ABSTRACT

A substrate processing apparatus includes a vacuum container, a rotary table provided inside the vacuum container, stages provided along a circumferential direction of the rotary table, and configured to support respective substrates disposed thereon, and a measuring instrument configured to measure characteristics of at least one substrate among the substrates disposed on the stages, wherein the stages are configured to be rotatable relative to the rotary table, wherein the measuring instrument is provided on a circumference of a circle that is centered on a central axis of the rotary table and passes through the stages in a plan view seen from a direction perpendicular to an upper surface of the rotary table.

### CROSS-REFERENCE TO RELATED APPLICATIONS

The present application is based on and claims priority to Japanese patent application No. 2023-126379 filed on Aug. 2, 2023 with the Japanese Patent Office, the entire contents of which are hereby incorporated by reference.

### TECHNICAL FIELD

### 1. Field of the Invention

The disclosures herein relate to a substrate processing apparatus and a substrate map generating method.

### BACKGROUND

A technology to monitor a film thickness and a warping of a substrate disposed on a rotary table while rotating the rotary table is known (see e.g. the Patent Literature (PTL) 1 and 2).

### CITATION LIST

### Patent Literature

[PTL 1] Japanese Laid-Open Patent Publication No. 2010-206026
[PTL 2] Japanese Laid-Open Patent Publication No. 2019-016662

### SUMMARY

A substrate processing apparatus includes a vacuum container, a rotary table provided inside the vacuum container, stages provided along a circumferential direction of the rotary table, and configured to support respective substrates disposed thereon, and a measuring instrument configured to measure characteristics of at least one substrate among the substrates disposed on the stages, wherein the stages are configured to be rotatable relative to the rotary table, wherein the measuring instrument is provided on a circumference of a circle that is centered on a central axis of the rotary table and passes through the stages in a plan view seen from a direction perpendicular to an upper surface of the rotary table.

### BRIEF DESCRIPTION OF THE DRAWINGS

FIG. 1 is a cross-sectional view illustrating an example of a configuration of a substrate processing apparatus related to the present embodiment;

FIG. 2 is a plan view illustrating a configuration inside a vacuum container of the substrate processing apparatus of FIG. 1;

FIG. 3 is a perspective view illustrating a configuration of a rotary table and a stage of the substrate processing apparatus of FIG. 1;

FIG. 4 is a cross-sectional view illustrating a configuration inside a housing box of the substrate processing apparatus of FIG. 1;

FIG. 5 is a drawing describing a position in which a height measuring instrument is provided;

FIG. 6 is a drawing illustrating a position on the substrate measured after one rotation of the rotary table;

FIG. 7 is a drawing illustrating a position on the substrate measured after two rotations of the rotary table;

FIG. 8 is a drawing illustrating a position on the substrate measured after three rotations of the rotary table;

FIG. 9 is a drawing illustrating a position on the substrate measured after eight rotations of the rotary table; and

FIG. 10 is a drawing illustrating one example of a data table.

### DESCRIPTION OF THE PREFERRED EMBODIMENTS

Hereinafter, modes for performing the invention will be described with reference to the drawings. In the drawings, the same constituent elements are denoted with the same reference numerals, and redundant description thereabout may be omitted.

### (Substrate Processing Apparatus)

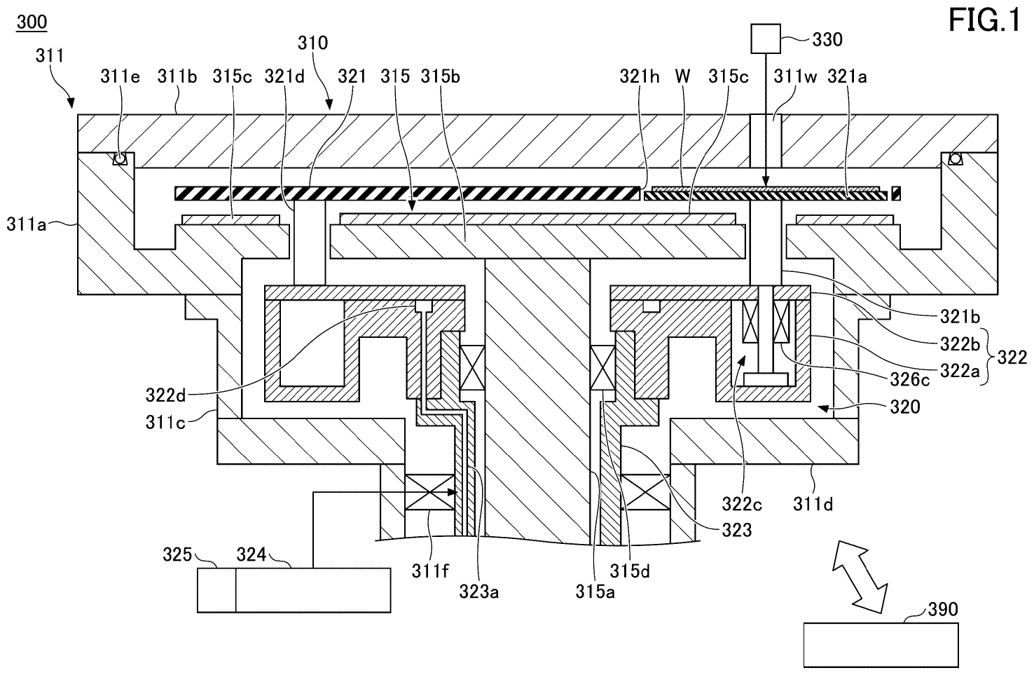

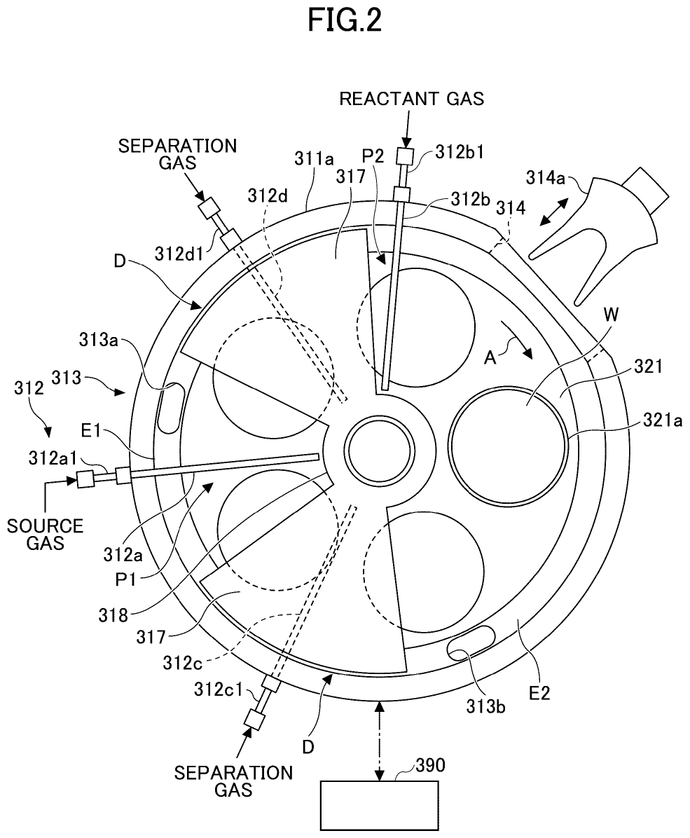

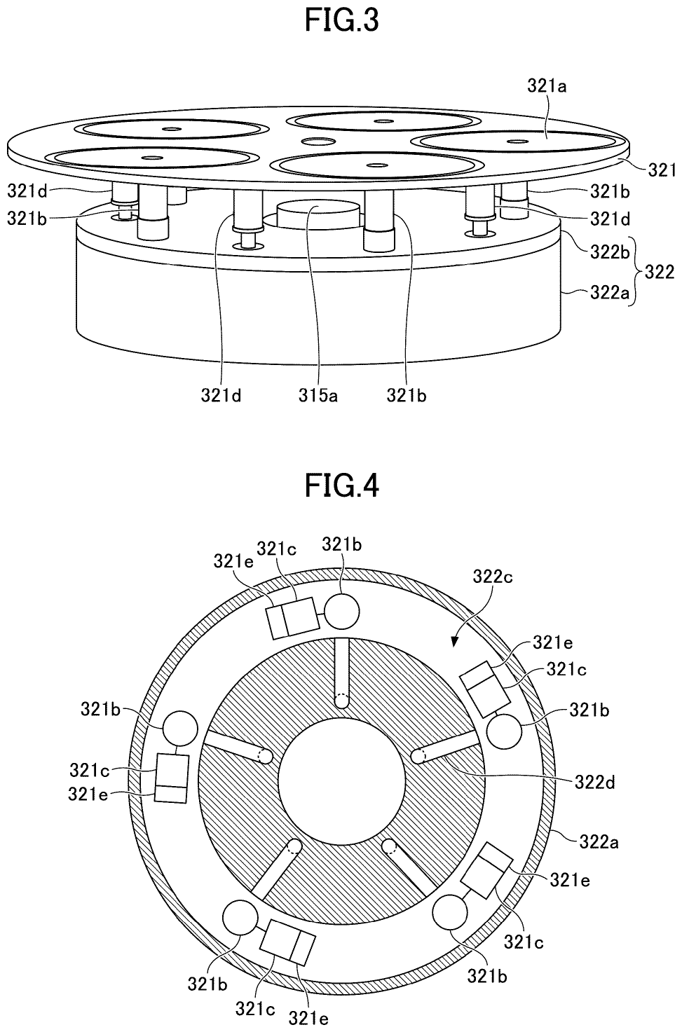

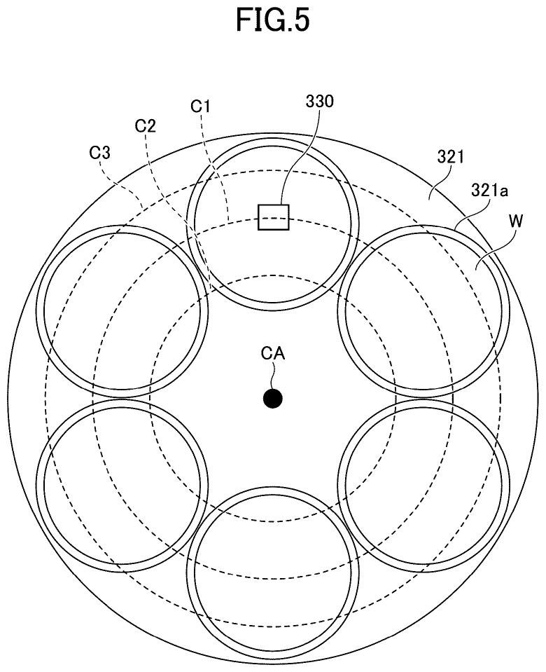

A substrate processing apparatus 300 according to the present embodiment is described referring to from FIG. 1 to FIG. 5. FIG. 1 is a cross-sectional view illustrating an example of a configuration of the substrate processing apparatus 300 related to the present embodiment. FIG. 2 is a plan view illustrating a configuration inside a vacuum container 311 of the substrate processing apparatus 300 of FIG. 1. In FIG. 2, an illustration of a top board 311b is omitted for convenience of description. FIG. 3 is a perspective view illustrating a configuration of a rotary table 321 and a stage 321a of the substrate processing apparatus 300 of FIG. 1. FIG. 4 is a cross-sectional view illustrating a configuration inside a housing box 322 of the substrate processing apparatus 300 of FIG. 1. FIG. 5 is a drawing describing a position in which a height measuring instrument 330 is provided.

The substrate processing apparatus 300 includes a processor 310, a rotary actuator 320, a height measuring instrument 330, and a controller 390.

The processor 310 has a vacuum container 311, a gas introduction portion 312, a gas exhaust 313, a carrier port 314, and a heater 315.

The vacuum container 311 is a processing container whose inside can be decompressed. The vacuum container 311 has a flat and substantially circular planar shape. The vacuum container 311 contains substrates W inside. The substrate W may be for example a semiconductor wafer.

The vacuum container 311 includes a main part 311a, a top board 311b, a lateral wall 311c, and a bottom board 311d. The main part 311a has a cylindrical shape. The top board 311b is hermetically and detachably disposed to the upper surface of the main part 311a through a seal portion 311e. A window 311w is provided in a part of the top board 311b. Quartz glass or the like is used for the window 311W to enable the interior of vacuum container 311 to be visible from the outside. The lateral wall 311c is connected to the lower surface of the main part 311a and has a cylindrical shape. The bottom board 311d is disposed hermetically to the bottom surface of the lateral wall 311c.

The gas introduction portion 312 includes a source gas nozzle 312a, a reactant gas nozzle 312b, and separation gas nozzles 312c and 312d. The source gas nozzle 312a, the reactant gas nozzle 312b, and the separation gas nozzles 312c and 312d are spaced apart from each other along the circumferential direction of the vacuum container 311 above the rotary table 321. For example, as Arrow A in FIG. 2 indicates that the separation gas nozzle 312c, the source gas nozzle 312a, the separation gas nozzle 312d, and the reactant gas nozzle 312b are arranged in this order clockwise (a direction of rotation of the rotary table 321) from the carrier port 314. Gas introduction ports 312al, 312b1, 312c1, and 312d1, which are base ends of the source gas nozzle 312a, the reactant gas nozzle 312b, and the separation gas nozzles 312c and 312d separately, are fixed to the outer wall of the main part 311a. The source gas nozzle 312a, the reactant gas nozzle 312b, and the separation gas nozzles 312c and 312d are introduced into the vacuum container 311 through the outer wall of the vacuum container 311, and attached to extend horizontally to the rotary table 321 along the radius of the main part 311a. The source gas nozzle 312a, the reactant gas nozzle 312b, and the separation gas nozzles 312c and 312d are formed from, for example, quartz.

The source gas nozzle 312a is connected to a source gas source (not shown) through piping, a flow controller, etc. (not shown). As a source gas, for example, a silicon-containing gas or a metal-containing gas is applicable. On the source gas nozzle 312a, discharge openings (not shown) opened to the rotary table 321 are arranged separately along the lengthwise direction of the source gas nozzle 312a. The source gas nozzle 312a discharges the source gas from the discharge openings. A region below the source gas nozzle 312a becomes a source gas adsorbing region P1 for the substrate W to adsorb the source gas.

The reactant gas nozzle 312b is connected to a reactant gas source (not shown) through piping a flow controller, etc. (not shown). As a reactant gas, for example, an oxidizing gas or a nitriding gas is applicable. On the reactant gas nozzle 312b, discharge openings (not shown) opened to the rotary table 321 are arranged separately along the lengthwise direction of the reactant gas nozzle 312b. The reactant gas nozzle 312b discharges the reactant gas from the discharge openings. A region below the reactant gas nozzle 312b becomes a reactant gas supplying region P2 in which the source gas adsorbed on the substrate W in the source gas adsorption region P1 is oxidized or nitrided.

Both of the separation gas nozzles 312c and 312d are connected to a separation gas source (not shown) through piping and a flow controller, etc. (not shown). As a separation gas, an inert gas, for example, an argon (Ar) gas or a nitrogen (N₂) gas is applicable. On the separation gas nozzles 312c and 312d, discharge openings (not shown) opened to the rotary table 321 are arranged separately along the lengthwise direction of the separation gas nozzle 312c and 312d. The separation gas nozzles 312c and 312d discharge the separation gas from the discharge openings.

The gas introduction portion 312 may include a purge gas introduction portion (not shown) below the rotary table 321. As a purge gas, for example, a same gas as the separation gas is applicable.

Two convex portions 317 are provided inside the vacuum container 311. The convex portion 317 is attached to the reverse surface of the top board 311b protruding toward the rotary table 321. The convex portion 317 constitutes a separation region D with the separation gas nozzles 312c and 312d. The convex portion 317 has a circular sector planar shape whose top is cut in an arc shape. The inner circular arc of the convex portion 317 is connected to the protrusion 318. The convex portion 317 is disposed with whose outer circular arc being along the inner wall of the main part 311a.

The gas exhaust 313 includes a first exhaust 313a and a second exhaust 313b. The first exhaust 313a is formed at the bottom of a first exhaust region E1. The first exhaust region E1 communicates with the source gas adsorbing region P1. The second exhaust 313b is formed at the bottom of a second exhaust region E2. The second exhaust region E2 communicates with the reactant gas supplying region P2. The first exhaust 313a and the second exhaust 313b are connected to an exhausting apparatus (not shown) including a vacuum pump and so on, through exhaust piping (not shown). A pressure control valve (not shown) is provided in the exhaust piping.

The carrier port 314 is provided on the lateral wall of the vacuum container 311. The carrier port 314 is an opening to transfer the substrate W between the rotary table 321 and a carrier arm 314a. The carrier port 314 is opened or closed by a gate valve (not shown).

A heater 315 includes a fixed shaft 315a, a heating element support 315b, and a heating element 315c.

The fixed shaft 315a has a cylindrical shape whose central axis is the center of the vacuum container 311. The fixed shaft 315a is provided inside a revolution axis 323 passing through the bottom board 311d. Between the outer wall of the fixed shaft 315a and the inner wall of the revolution axis 323, a seal portion 315d is provided. Consequently, the revolution axis 323 rotates on the fixed shaft 315a maintaining hermeticity inside the vacuum container 311. The seal portion 315d includes, for example, a magnetic fluid seal.

The heating element support 315b is fixed on the top of the fixed shaft 315a, and has a disk shape. The heating element support 315b supports the heating element 315c.

The heating element 315c is provided on the upper surface of the heating element support 315b. The heating element 315c may be provided in the main part 311a, in addition to the upper surface of the heating element support 315b. The heating element 315c heats the substrate W.

The rotary actuator 320 has the rotary table 321, the housing box 322, the revolution axis 323, and a revolution motor 324.

The rotary table 321 is provided inside the vacuum container 311. The rotary table 321 has a rotation center at the center of the vacuum container 311. The rotary table 321 has, for example, a disk shape. The rotary table 321 is formed from, for example, quartz. The rotary table 321 is connected to the housing box 322 through connectors 321d. The rotary table 321 has a plurality (e.g. five) of openings 321h. The openings 321h are provided separately from each other along the direction of rotation of the rotary table 321. Each opening 321h is provided at distant positions from the rotation center of the rotary table 321.

The stage 321a is provided in a coincident position with the opening 321h in a plan view. The plurality of the stages 321a are provided along the direction of rotation of the rotary table 321. The number of the stages 321a is same as the number of the openings 321h. Each stage 321a is provided at distant positions from the rotation center of the rotary table 321. Each stage 321a has a disk shape slightly larger than the substrate W. Each stage 321a is formed from, for example, quartz. Each stage 321a may be formed from highly thermal conductive materials such as Al₂O₃, AlN, SiC, and the like. The substrate W is disposed on respective stages 321a. Each stage 321a is configured to be rotatable together with the rotary table 321. Each stage 321a is connected to a rotation motor 321c through a rotation axis 321b, and configured to be relatively rotatable to the rotary table 321. A detailed configuration of the rotary table 321 and the stage 321a is described below.

The rotation axis 321b connects the lower surface of the stage 321a and the rotation motor 321c. The rotation axis 321b transmits power of the rotation motor 321c to the stage 321a. The rotation axis 321b is configured to be rotatable on the center of the stage 321a as the rotation center. A plurality of the rotation axes 321b are installed along the direction of the rotation of the rotary table 321. The number of the rotation axes 321b is same as the number of the stages 321a. The rotation axis 321b passes through the ceiling 322b of the housing box 322. A seal portion 326c is installed in a through hole of the ceiling 322b to maintain the hermeticity inside the housing box 322. The seal portion 326c includes, for example, a magnetic fluid seal.

The rotation motor 321c is contained inside the housing box 322. The rotation motor 321c rotates the stage 321a with respect to the rotary table 321 through the rotation shaft 321b. Consequently, the substrate W rotates. The rotation motor 321c is, for example, a servomotor. A first encoder 321e that detects a rotation angle of the rotation axis 321b is provided in the rotation motor 321c. The rotation angle of the rotation axis 321b detected by the first encoder 321e is transmitted to the controller 390 and utilized by the controller 390 to determine the position of the substrate W disposed on the stage 321a.

The connector 321d connects the lower surface of the rotary table 321 and the upper surface of the housing box 322. The plurality of the connectors 321d are provided, for example, along the circumferential direction of the rotary table 321. Connectors 321d and rotation axes 321b may be installed on the same circumference. Connectors 321d and rotation axes 321b may be installed alternately along the distance of the circumferential direction of the rotary table 321.

The housing box 322 is installed below the rotary table 321 inside the vacuum container 311. The housing box 322 is connected to the rotary table 321 through connectors 321d, and configured to be rotatable integrally with the rotary table 321. The housing box 322 may be configured to be liftable inside the vacuum container 311 by a lift (not shown). The housing box 322 has a main part 322a and the ceiling 322b.

The main part 322a is formed in a U-shape in a cross-sectional view, and formed into a ring shape along the direction of rotation of the rotary table 321.

The ceiling 322b is installed above the main part 322a. The ceiling 322b forms a container 322c which is separated from the inside of the vacuum container 311 with the main part 322a by covering an opening of the main part 322a which is formed concave in a cross-sectional view.

The container 322c is formed rectangularly in a cross-sectional view, and is formed into a ring shape along the direction of rotation of the rotary table 321. The container 322c contains the rotation motor 321c. A communication route 322d is formed in the main part 322a. The communication path communications the outside of the substrate processing apparatus 300 to the container 322c. Consequently, air is introduced into the container 322c from the outside of the substrate processing apparatus 300 through the communication route 322d. Consequently, the inside of the container 322c is cooled and the inside of the container 322c is maintained at atmospheric pressure.

The revolution shaft 323 is fixed to the bottom of the housing box 322. The revolution axis 323 is provided so as to pass through the bottom board 311d. The revolution axis 323 transmits power of the revolution motor 324 to the rotary table 321 and the housing box 322 to integrally rotate the rotary table 321 and the housing box 322. A seal portion 311f is provided in a through hole of the bottom board 311d to maintain the hermeticity inside the vacuum container 311. The seal portion 311f includes for example a magnetic fluid seal.

A through hole 323a is provided inside the revolution axis 323. The through hole 323a is connected to the communication route 322d to function as a fluid passage to introduce air into the housing box 322. The through hole 323a also functions as a wiring duct to introduce power lines to drive the rotation motor 321c, and signal lines. The through holes 323a are provided, for example, in the same number as the rotation motors 321c.

The revolution motor 324 rotates the rotary table 321 to the vacuum container 311 through the revolution axis 323. Consequently, the substrate W revolves. The revolution motor 324 is, for example, a servomotor. A second encoder 325 that detects a rotation angle of the revolution axis 323 is provided in the revolution motor 324. The rotation angle of the revolution axis 323 detected by the second encoder 325 is transmitted to the controller 390 and utilized by the controller 390 to determine the position of the substrate W disposed on the stage 321a.

The height measuring instrument 330 measures the height of the substrate W disposed on the stage 321a without making any contact with the stage 321a. As shown in FIG. 1, the height measuring instrument 330 is provided above the window 311w of the top board 311b. As shown in FIG. 5, the height measuring instrument 330 is provided above the circumference of a first circle which is centered on the central axis CA of the rotary table 321, and which passes through the stages 321a in a plan view seen from a direction perpendicular to the upper surface of the rotary table 321. In the present embodiment, the first circle is a circle C1 which passes through the centers of the stages 321a. In this case, it is easy to acquire distribution of warping over the whole surface of the substrate W. The first circle may be a circle C2 which passes through a position nearer to the central axis CA than the centers of the stages 321a are. The first circle may be a circle C3 which passes through a position farther from the central axis CA than the centers of the stages 321a are.

The height measuring instrument 330 is, for example, a laser displacement meter. The height measuring instrument 330 measures a distance from the height measuring instrument 330 to the substrate W by irradiating the surface of the substrate W disposed on the stage 321a with a laser, and receives the laser reflected at the upper surface of the substrate W. As the rotary table 321 rotates and the substrate W travels along with the rotary table 321, that is, in the direction of rotation, the height measuring instrument 330 detects variations in the distance to the upper surface of the substrate W. The variations reflect the unevenness of the surface of the substrate W.

The controller 390 controls each portion of the substrate processing apparatus 300. The controller 390 may be, for example, a computer. Computer programs to perform an operation of each portion of the substrate processing apparatus 300 is stored in a storage medium. The storage medium may be, for example, a flexible disk, a compact disc, a hard disk, a flash memory, a DVD, etc.

The controller 390 performs a process S1 to measure the height of the substrate W by using the height measuring instrument 330, controlling the rotation motor 321c and the revolution motor 324, and rotating the rotary table 321, for each of a plurality of positional relationships in which relative angles between the rotary table 321 and the stage 321a corresponding to the substrate are respectively different.

The step S1 includes measuring the height of the substrate W by the height measuring instrument 330, for example, while rotating the stage 321a relative to the rotary table 321. Steps: forming films to the substrates W disposed on respective stages 321a, etching, and the like, tend to be performed while rotating the stage 321a relative to the rotary table 321, in order to ensure uniformity over the surface. Therefore, when the height of the substrate W is measured by the height measuring instrument 330, for example, while rotating the stage 321a relative to the rotary table 321, the height of the substrate W can be measured while the processes to the substrate W are performed. Consequently, all the heights of the substrates W can be measured without decreasing productivity. The process S1 may include measuring the height of the substrate W by the height measuring instrument 330 while keeping the stage 321a stationary relative to the rotary table 321.

The process S1 may include rotating the rotary table 321 one revolution per rotating the stage 321a at a first angle relative to the rotary table 321. The first angle may be such that 180° is divisible by the first angle. In this case, measuring points to measure the height of the substrate W are positioned approximately uniformly along the circumferential direction of the substrate W. The process S1 may include rotating the rotary table 321 as much times as the quotient of 180° divided by the first angle, or more. In this case, the measuring points are positioned entirely along the circumferential direction of the substrate W. The first angle is preferably 45° or less, more preferably 22.5° or less. In this case, since the measuring points along the circumferential direction of the substrate W increase, in a process S2 described below, a warping map accurate in the circumferential direction of the substrate W can be generated.

The controller 390 performs a process S2 to generate a warping map illustrating the distribution of the height of the substrate W over the surface of the substrate W, according to the height of the substrate W measured by the height measuring instrument 330. For example, the controller 390 determines the positions of the substrates W disposed on respective stages 321a according to the rotation angles of the rotation axes 321b detected by the first encoder 321e, and the rotation angle of the revolution axis 323 detected by the second encoder 325. The controller 390 stores correspondences between the detected positions of the substrates W and the heights of the substrates W measured by the height measuring instrument 330 on a storage. Information of the correspondences between the positions of the substrates W and the heights of the substrate W are, for example, a data table. The controller 390 generates the warping map according to the correspondence information stored on the storage.

The controller 390 performs the step S1, for example, during the process to the substrates W disposed on respective stages 321a. In this case, a warping map during the process can be generated. Therefore, warping of the substrates W during the process can be observed. Moreover, warping of all the substrates W can be observed without decreasing productivity. The controller 390 may perform the process S1 after the substrates W are disposed on the respective stages 321a and before the process to respective substrates W is performed. In this case, a warping map before the process can be generated. Therefore, warping of the substrates W before the process can be observed. The controller 390 may perform the process S1 after the process to respective substrates W disposed on the respective stages 321a is performed and before the substrates W are removed from the respective stages 321a. In this case, a warping map after the process can be generated. Therefore, warping of the substrates W after the process can be observed. The controller 390 may perform the process S1 both before and after the process. In this case, the warping of the substrate W caused by the process to the substrate W can be observed by comparing a warping map before the process and a warping map after the process.

### (Substrate Processing Method)

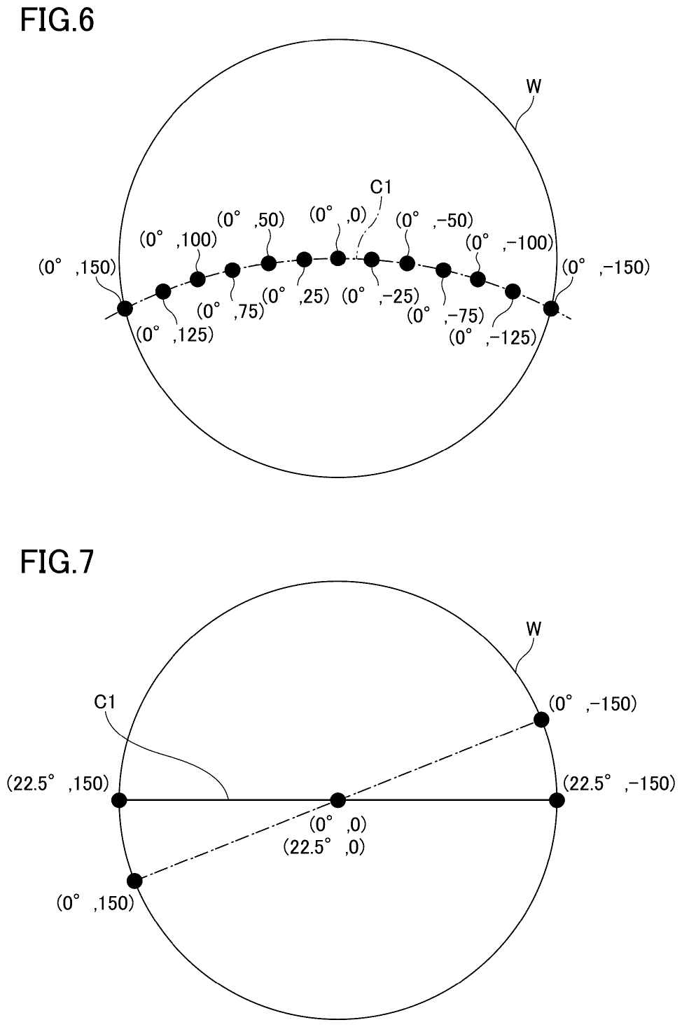

Referring to from FIG. 6 to FIG. 9, as one example of a substrate processing method related to the present embodiment, a substrate processing method using the substrate processing apparatus 300 is described. The substrate processing method related to the present embodiment is performed controlled by the controller 390. The substrate processing method related to the present embodiment includes a substrate map generating method to generate a substrate map illustrating a distribution of the characteristics of the substrate W over the surface of the substrate W. Hereinafter, a case of generating a warping map as one example of a substrate map is described.

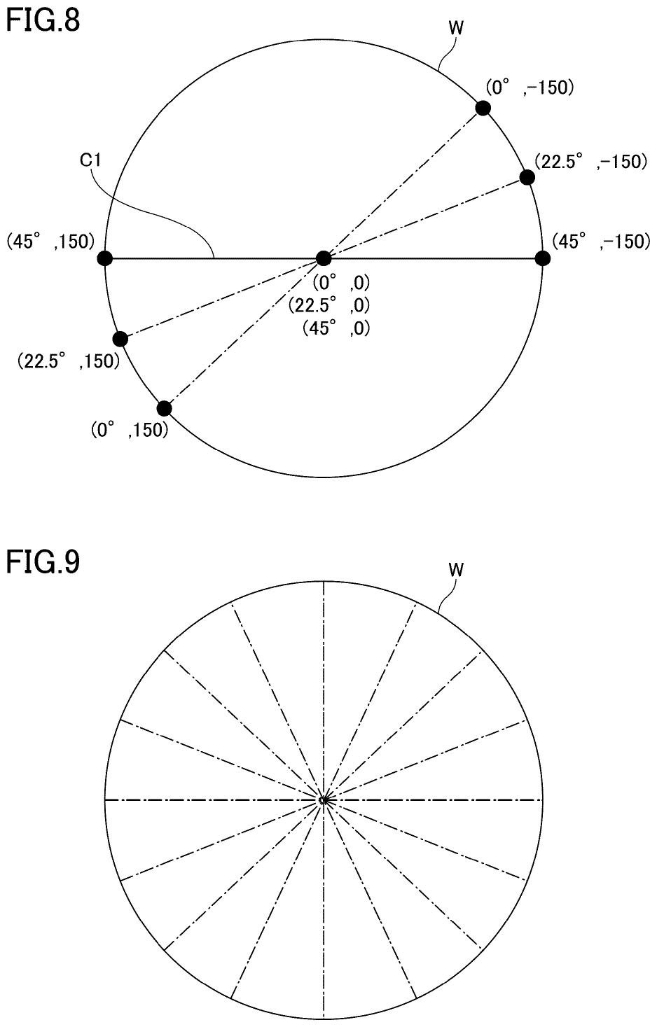

FIG. 6 is a drawing illustrating a position on the substrate W measured after one rotation of the rotary table 321. FIG. 7 is a drawing illustrating a position on the substrate W measured after two rotations of the rotary table 321. FIG. 8 is a drawing illustrating a position on the substrate W measured after three rotations of the rotary table 321. FIG. 9 is a drawing illustrating a position on the substrate W measured after eight rotations of the rotary table 321.

First, the not shown gate valve is opened, and the substrates W is transferred to the stages 321a of the rotary table 321 through the carrier port 314 by the carrier arm 314a. Transferring the substrates W is performed while keeping the stages 321a stationary at the same angular position as the carrier port 314. Transferring the substrates W is performed rotating intermittently the rotary tables 321, and the substrates W are disposed on the five respective stages 321a of the rotary table 321.

Subsequently, the gate valve is closed, and the inside of the vacuum container 311 is decompressed by the not shown exhausting apparatus. Afterwards, the inside of the vacuum container 311 is adjusted to the processing pressure by controlling the pressure control valve, supplying the separation gas from the separation gas nozzles 312c and 312d at a predetermined flow. Thereafter, the heating element 315c heats the substrates W disposed on respective stages 321a.

Subsequently, the controller 390 may perform the process S1 before the process to the substrates W disposed on respective stages 321a is performed. In this case, a warping map before the process can be generated. Therefore, warping of the substrate W before the process can be observed. Specifically, the height measuring instrument 330 measures the height of the substrate W disposed on the stage 321a in the following manner.

First, an angle of the stage 321a to the rotary table 321 is configured to be 0°, and the rotary table 321 is rotated one revolution while keeping the angle of the stage 321a to be 0° relative to the rotary table 321. The height measuring instrument 330 measures the height of the substrate W disposed on the stage 321a while the rotary table 321 is rotated one revolution. Consequently, as shown in FIG. 6, the height measuring instrument 330 can measure the height of the substrate W at a plurality of places (in the present embodiment, fifteen places) on the circular arc of the circle C1 which passes through the center of the stage 321a, centered on the central axis CA of the rotary table 321. In FIG. 6, the fifteen places on the circular arc of the circle C1 are shown, but this number of measuring points that the height measuring instrument 330 measures is by no means a limitation. In FIG. 6, a position (0°, −150°) is at 0° of the first angle, and it means that the position is −150 mm. Other positions are the same.

After rotating the rotary table 321 one revolution, the stages 321a are rotated 22.5° relative to the rotary table 321. Subsequently, the rotary table 321 is rotated one revolution, maintaining the angle of the stages 321a to the rotary table 321 to be 22.5°. The height measuring instrument 330 measures the height of the substrates W disposed on the respective stages 321a while the rotary table 321 is rotated one revolution. Consequently, as shown in a solid line in FIG. 7, the height measuring instrument 330 can measure the height of the substrates W at a plurality of places (in the present embodiment, fifteen places) on the circular arc of the circle C1 which passes through the center of the stage 321a centered on the central axis CA of the rotary table 321. Note that, in FIG. 7, three places on the circular arc of the circle C1 are shown for convenience of description. Moreover, in FIG. 7, the circular arc of the C1 is represented as a straight line for convenience of description.

After rotating the rotary table 321 one revolution, the stages 321a are rotated another 22.5° to the rotary table 321. That is, the angle of the stages 321a to the rotary table 321 is configured to be 45°. Subsequently, the rotary table 321 is rotated one revolution, maintaining the angle of the stages 321a to the rotary table 321 to be 45°. The height measuring instrument 330 measures the height of the substrate W disposed on the stage 321a while the rotary table 321 is rotated one revolution.

Consequently, as shown in a solid line in FIG. 8, the height measuring instrument 330 can measure the height of the substrates W at a plurality of places (in the present embodiment, fifteen places) on the circular arc of the circle C1 which passes through the center of the stage 321a centered on the central axis CA of the rotary table 321. Note that, in FIG. 8, three places on the circular arc of the circle C1 are shown for convenience of description. Moreover, in FIG. 8, the circular arc of the C1 is represented as a straight line for convenience of description.

Thus, the stages 321a are rotated 22.5° to the rotary table 321 as the rotary table 321 is rotated one revolution, and the rotary table 321 is continuously rotated until the angle of the stages 321a to the rotary table 321 reaches 157.5°. That is, the rotary table 321 is rotated eight times in total. The height measuring instrument 330 measures the heights of the substrates W disposed on the respective stages 321a while the rotary table 321 is rotated. Therefore, the height measuring instrument 330 can measure the height of the substrate W at positions on a plurality of curved lines (in the present embodiment, sixteen) extending radially from the center of the substrate W, as represented as chain lines in FIG. 9. That is, the height of the substrate W over the surface of the substrate W can be measured by a single height measuring instrument 330, without using a plurality of height measuring instruments 330.

Subsequently, the controller 390 performs the process S2 to generate a warping map illustrating the distribution of the height of the substrate W over the surface of the substrate W according to the height of the substrate W, measured by the height measuring instrument 330. Specifically, the controller 390 generates a warping map in the following manner.

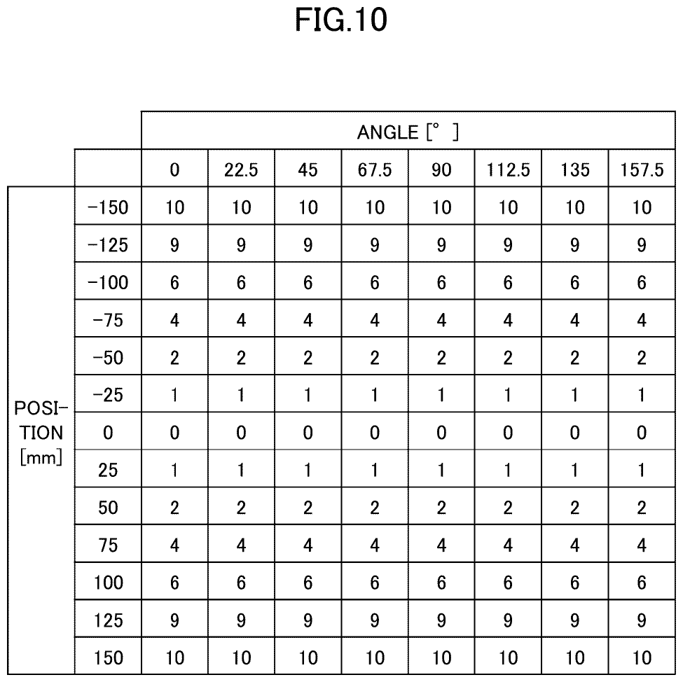

First, the controller 390 determines the positions of the substrates W disposed on respective stages 321a according to the rotation angles of the rotation axes 321b detected by the first encoder 321e, and the rotation angle of the revolution axis 323 detected by the second encoder 325. The controller 390 stores correspondences between the detected positions of the substrates W and the heights of the substrates W measured by the height measuring instrument 330 on a storage. Information of the correspondences between the positions of the substrates W and the heights of the substrate W are for example a data table. FIG. 10 is a drawing illustrating one example of a data table. As shown in FIG. 10, the data table shows the correspondences between the fifteen positions of the substrates W at respective angles of the stage 321a to the rotary table 321, and the heights of the substrate W. The angles of the stage 321a to the rotary table 321 are 0°, 22.50°, 45°, 67.5°, 90°, 112.5°, 135°, and 157.5°. The positions of the fifteen places at respective angles are −150 mm, −125 mm, −100 mm, −75 mm, −50 mm, −25 mm, 0 mm, 25 mm, 50 mm, 75 mm, 100 mm, 125 mm, and 150 mm.

Thereafter, the controller 390 generates the warping map illustrating the distribution of the height of the substrate W over the surface of the substrate W according to the correspondence information stored on the storage.

Subsequently, the process to the substrates W disposed on respective stages 321a is performed. First, the rotary table 321 is continuously rotated. At this time, the stage 321a may be rotated relative to the rotary table 321. In this case, the uniformity over the surface can be ensured. Thereafter, the source gas is supplied from the source gas nozzle 312a, and the reactant gas is supplied from the reactant gas nozzle 312b. When the substrate W passes through the source gas adsorbing region P1, the source gas supplied from the source gas nozzle 312a is adsorbed to the upper surface of the substrate W. The substrate W which has adsorbed the source gas enters the reactant gas supplying region P2 after being purged, passing through the separation region D which has the separation gas nozzle 312d, by the rotation of the rotary table 321. In the reactant gas supplying region P2, the source gas adsorbed to the upper surface of the substrate W reacts with the reactant gas supplied from the reactant gas nozzle 312b, and a reaction product accumulates on the upper surface of the substrate W.

The substrate W which has passed through the reactant gas supplying region P2 passes through the source gas adsorbing region P1 again, after being purged, passing through the separation region D which has the separation gas nozzle 312c. Subsequently, the source gas supplied from the source gas nozzle 312a is adsorbed to the upper surface of the substrate W.

Thus, the rotary table 321 is continuously rotated, supplying the source gas from the source gas nozzle 312a, and supplying the reactant gas from the reactant gas nozzle 312b. Consequently, a film of the reaction product is formed on the upper surface of the substrate W.

The controller 390 may perform the process S1 during the process to the substrates W disposed on respective stages 321a. In the process S1 during the process, the height measuring instrument 330 measures the height of the substrate W over the surface of the substrate W, rotating the rotary table 321, at a state rotating the stage 321a relative to the rotary table 321. In this case, a warping map during the process can be generated. Therefore, warping of the substrates W during the process can be observed. Moreover, warping of all the substrates W can be observed without decreasing productivity.

The controller 390 may perform the process S1 after the process to respective substrates W disposed on the respective stages 321a is performed. In this case, a warping map after the process can be generated. Therefore, warping after the process can be observed. Moreover, the warping of the substrate W caused by the process to the substrate W can be observed by comparing a warping map before the process and a warping map after the process.

Subsequently, the substrates W disposed on respective stages 321a are removed from inside the vacuum container 311 in the reverse order of the steps when the substrates W were carried into the vacuum container 311.

Further, the present invention is not limited to this embodiment, but various variations and modifications may be made without departing from the scope of the present invention.

In an above-mentioned embodiment, a case that the controller 390 generates the warping map according to the height of the substrate W measured by the height measuring instrument 330 is described, but the present disclosure is not limited to this. For example, by using a film thickness measuring instrument instead of the height measuring instrument 330, the controller 390 can generate a film thickness map illustrating a distribution of the film thickness over the surface of the substrate W according to the thickness of the substrate W measured by the film thickness measuring instrument. A type of the film thickness measuring instrument is not particularly limited, for example an interference spectroscope. For example, by using a temperature measuring instrument instead of the height measuring instrument 330, the controller 390 can generate a temperature map illustrating a distribution of the temperature over the surface of the substrate W. The type of the temperature-measuring instrument is not particularly limited and may be, for example, a radiation thermometer. Thus, according to the embodiments, substrate maps illustrating characteristics of the substrate W over the surface of the substrate W can be generated.

According to the present disclosure, a substrate map can be generated.

What is claimed is:

1. A substrate processing apparatus comprising:
a vacuum container;
a rotary table provided inside the vacuum container;
stages provided along a circumferential direction of the rotary table, and configured to support respective substrates disposed thereon; and
a measuring instrument configured to measure characteristics of at least one substrate among the substrates disposed on the stages,
wherein the stages are configured to be rotatable relative to the rotary table,
wherein the measuring instrument is provided on a circumference of a circle that is centered on a central axis of the rotary table and passes through the stages in a plan view seen from a direction perpendicular to an upper surface of the rotary table.

2. The substrate processing apparatus according to claim 1, wherein the circle passes through centers of the stages.

3. The substrate processing apparatus according to claim 1 further comprising:
a controller,
wherein the controller is configured to:
(a) measure characteristics of the substrate by using the measuring instrument while rotating the rotary table, for each of a plurality of positional relationships in which relative angles between the rotary table and one of the stages corresponding to the substrate are respectively different; and
(b) generate a substrate map illustrating a distribution of the characteristics of the substrate over a surface of the substrate based on the characteristic of the substrate.

4. The substrate processing apparatus according to claim 3, wherein (a) includes measuring the characteristics of the substrate by using the measuring instrument while rotating the stage relative to the rotary table.

5. The substrate processing apparatus according to claim 3, wherein (a) includes measuring the characteristics of the substrate by using the measuring instrument while keeping the stage stationary relative to the rotary table.

6. The substrate processing apparatus according to claim 5, wherein (a) includes rotating the rotary table one revolution each time the stage is rotated by a first angle relative to the rotary table, wherein the first angle is such that 180° is divisible by the first angle.

7. The substrate processing apparatus according to claim 5, comprising rotating the rotary table one revolution each time the stage is rotated by a first angle relative to the rotary table, wherein (a) includes rotating the rotary table a number of revolutions equal to a quotient of 180° divided by the first angle, or more revolutions.

8. The substrate processing apparatus according to claim 1, wherein the measuring instrument is a height measuring instrument, a film thickness measuring instrument, or a temperature measuring instrument.

9. A method of generating a substrate map for a substrate in a substrate processing apparatus, which includes:
a vacuum container;
a rotary table provided inside the vacuum container;
stages provided along a circumferential direction of the rotary table, and configured to support respective substrates disposed thereon; and
a measuring instrument configured to measure characteristics of at least one substrate among the substrates disposed on the stages,
wherein the stages are configured to be rotatable relative to the rotary table, and
wherein the measuring instrument is provided on a circumference of a circle that is centered on a central axis of the rotary table and passes through the stages in a plan view seen from a direction perpendicular to an upper surface of the rotary table,
the method comprising:
(a) measuring characteristics of the substrate by using the measuring instrument while rotating the rotary table, for each of a plurality of positional relationships in which relative angles between the rotary table and one of the stages corresponding to the substrate are respectively different; and
(b) generating a substrate map illustrating a distribution of the characteristics of the substrate over a surface of the substrate based on the characteristic of the substrate.
